(19) United States
(12) Patent Application Publication
(10) Pub. No.: US 2025/0125184 A1
(43) Pub. Date: Apr. 17, 2025

(54) CERAMIC SUSCEPTOR AND METHOD OF MANUFACTURING SAME

(71) Applicant: MiCo Ceramics Ltd., Anseong-si, Gyeonggi-do (KR)

(72) Inventors: Min-Ho JI, Anseong-si (KR); Gi-Myeong SUNG, Anseong-si (KR)

(21) Appl. No.: 18/902,536

(22) Filed: Sep. 30, 2024

(30) Foreign Application Priority Data
Oct. 12, 2023 (KR) 10-2023-0136074

(51) Int. Cl. H01L 21/687; C23C 14/50; C23C 16/458; C23C 16/46; H01L 21/67

(52) U.S. Cl. CPC H01L 21/68785; C23C 14/50; C23C 16/4586; C23C 16/463; H01L 21/67109

(57) ABSTRACT

The present disclosure relates to a ceramic susceptor and a method of manufacturing the same. The ceramic susceptor includes: a base substrate having a gas flow path configured to supply cooling gas; an insulating plate fixed on the base substrate and having a gas hole; and a pore structure to allow the gas flow path and the gas hole to communicate with each other between the base substrate and the insulating plate, the pore structure including a support fixed to a groove of the base substrate and having a communication hole configured to communicate with the gas flow path, a porous filter embedded between the communication hole and the gas hole on the support, and a fluid stopper disposed on an outer side surface of the support.

### CROSS-REFERENCE TO RELATED APPLICATION(S)

This application is based on and claims priority under 35 U.S.C. 119 to Korean Patent Application No. 10-2023-0136074, filed on Oct. 12, 2023, in the Korean Intellectual Property Office, the disclosure of which is herein incorporated by reference in its entirety.

### BACKGROUND OF THE INVENTION

### 1. Field of the Invention

The present disclosure relates to a ceramic susceptor and, in particular, to a ceramic susceptor in which cooling gas holes are protected and a method of manufacturing the same.

### 2. Description of the Prior Art

In general, a semiconductor device or a display device is manufactured by sequentially laminating a plurality of thin film layers including a dielectric layer and a metal layer on a glass substrate, a flexible substrate, or a semiconductor wafer substrate and then patterning the thin film layers. These thin film layers are sequentially deposited on the substrate through a chemical vapor deposition (CVD) process or a physical vapor deposition (PVD) process. The CVD process includes a low-pressure CVD (LPCVD) process, a plasma-enhanced CVD (PECVD) process, a metal-organic CVD (MOCVD) process, and the like.

In the CVD and PVD apparatuses, a ceramic susceptor is placed to support a glass substrate, a flexible substrate, a semiconductor wafer substrate, or the like and to carry out the semiconductor process. The ceramic susceptor may include a chuck electrode installed in the CVD and PVD apparatuses to support a substrate, and a heating wire configured to heat the substrate in a heat treatment process or the like. In addition, the ceramic susceptor may include a radio frequency (RF) electrode instead of the heating wire, or may further include an RF electrode to be also used to form plasma during the etching process of the thin film layers formed on the substrate.

In the ceramic susceptor described above, a base substrate and an insulating plate bonded thereto have a specific cooling structure in order to uniformly cool the substrate on the insulating plate using an external cooling gas. In general, the cooling structure is configured to allow the cooling gas flow path in the base substrate to communicate with the gas holes in the insulating plate. In the process of bonding the base substrate and the insulating plate using a liquid bonding agent, various attempts are being made to prevent the bonding agent from penetrating into the gas holes.

For example, the gas hole structure in the conventional ceramic susceptor is a straight-line structure through which the process gas (e.g., He) is directly supplied. However, in order to improve the distribution of process gas supply and prevent arcing on the surface, as illustrated in FIG. 5, a porous ceramic structure 4 is inserted between a gas flow path in a base substrate 20 and a gas hole 3 in an insulating plate 13. However, there is a problem in that the gas hole may become clogged due to the bonding agent 12 used for bonding the base substrate 20 and the insulating plate 13, and it is not easy to control the volume of the bonding agent 12 to prevent this phenomenon. In addition, in this structure, contamination or the like around the gas hole may cause gas supply failure, particle generation, arcing, or the like. In particular, this issue is serious in a high-power susceptor or the like for a high-aspect ratio contact (HARC) process.

### SUMMARY OF THE INVENTION

The present disclosure has been made to solve the above-mentioned problems, and provides a ceramic susceptor and a method for manufacturing the same, in which a fluid stopper structure is applied to the bonding structure of a base substrate and an insulating plate to make it easy to adjust the volume of the bonding agent during the bonding process, thereby preventing clogging of the gas holes in a high-power ceramic susceptor for a high aspect ratio contact (HARC) process and reducing contamination around the gas holes to minimize arcing.

First, in view of the foregoing, a ceramic susceptor according to an aspect of the present disclosure may include: a base substrate having a gas flow path configured to supply cooling gas; an insulating plate fixed on the base substrate and having a gas hole; and a pore structure configured to allow the gas flow path and the gas hole to communicate with each other between the base substrate and the insulating plate, the pore structure including a support fixed to a groove of the base substrate and having a communication hole configured to communicate with the gas flow path, a porous filter embedded between the communication hole and the gas hole on the support, and a fluid stopper disposed on an outer side surface of the support. A bonding agent bonding the base substrate and the insulating plate may be confined in a space between the base substrate and the support by the fluid stopper, and the fluid stopper may be made of silicone, and the porous filter extends beyond a top surface of the support and protrude toward the insulating plate.

The fluid stopper includes a ring-shaped sealing member disposed in a groove formed along the perimeter of the support.

The ring-shaped sealing member may include a rectangular, circular, oval, or trapezoidal cross-sectional shape.

In addition, a ceramic susceptor according to another aspect of the present disclosure includes: a base substrate having a gas flow path configured to supply cooling gas; an insulating plate fixed on the base substrate and having a gas hole; and a pore structure configured to allow the gas flow path and the gas hole to communicate with each other between the base substrate and the insulating plate, the pore structure including a support fixed to a groove of the base substrate and having a communication hole configured to communicate with the gas flow path, a porous filter embedded between the communication hole and the gas hole on the support, and a fluid stopper disposed on an outer side surface of the support. A bonding agent bonding the base substrate and the insulating plate may be confined in a space between the base substrate and the support by the fluid stopper, and the fluid stopper includes a protrusion formed along the perimeter of the support.

In addition, a ceramic susceptor according to another aspect of the present disclosure includes: a base substrate having a gas flow path configured to supply cooling gas; an insulating plate fixed on the base substrate and having a gas hole; and a pore structure configured to allow the gas flow path and the gas hole to communicate with each other between the base substrate and the insulating plate, the pore structure including a support fixed to a groove of the base substrate and having a communication hole configured to communicate with the gas flow path, a porous filter embedded between the communication hole and the gas hole on the support, and a fluid stopper disposed on an outer side surface of the support. A bonding agent bonding the base substrate and the insulating plate may be confined in a space between the base substrate and the support by the fluid stopper, and the fluid stopper includes a protrusion formed on the base substrate to be in contact with the perimeter of the support.

The gap between the base substrate and the support within the groove of the base substrate may be 0.1 to 0.8 mm.

The fluid stopper may be disposed at a position of 50 to 80% of the total height of the support.

The bonding agent may have a dielectric strength of 20 kV/mm or more and a volume resistance of 10¹² Ωcm or more.

In addition, a method of manufacturing a ceramic susceptor according to another aspect of the present disclosure includes: placing a support having a communication hole communicating with a gas flow path in a groove of a base substrate having a gas flow path configured to supply cooling gas; placing a porous filter on the support to be in contact with the communication hole; forming a bonding layer using a bonding agent; attaching a ceramic sheet; and forming an electrode layer. During the forming of the bonding layer and the attaching of the ceramic sheet, the bonding agent is confined in a space between the base substrate and the support by a fluid stopper, and the fluid stopper includes a protrusion formed along the perimeter of the support, or a protrusion formed on the base substrate to be in contact with the perimeter of the support.

In the attaching of the ceramic sheet, a gas hole may be processed in advance in the ceramic sheet at a position corresponding to the porous filter.

The method may further include processing a gas hole penetrating from outside a position corresponding to the porous filter to a position of the porous filter after the forming of the electrode layer.

In addition, a method of manufacturing a ceramic susceptor according to another aspect of the present disclosure includes: placing a porous filter in a groove of an insulating plate including an electrode layer to be in contact with a gas hole; placing a support having a communication hole configured to communicate with the porous filter such that the communication hole is aligned with the position of the porous filter; forming a bonding layer on the support using a bonding agent; and placing the base substrate such that a groove of the base substrate having a gas flow path configured to supply cooling gas is seated on the support having the communication hole configured to communicate with the gas flow path. During the forming of the bonding layer and the placing of the base substrate, the bonding agent is confined in a space between the base substrate and the support by a fluid stopper, and the fluid stopper includes a protrusion formed along the perimeter of the support, or a protrusion formed on the base substrate to be in contact with the perimeter of the support.

The gap between the base substrate and the support within the groove of the base substrate may be 0.1 to 0.8 mm.

The bonding agent may be filled to 50 to 80% of the total height of the support by the fluid stopper.

According to a ceramic susceptor and a method of manufacturing the same of the present disclosure, it is possible to provide a ceramic susceptor in which, by applying a fluid stopper structure to the bonding structure of the base substrate and the insulating plate, which, in a high-power ceramic susceptor for a high aspect ratio contact (HARC) process, or the like, makes it easy to adjust the volume of the bonding agent during the bonding process, clogging of gas holes can be prevented, and contamination around the gas holes can be reduced, thereby minimizing the occurrence of arcing.

In addition, according to a ceramic susceptor and a method of manufacturing the same of the present disclosure, it is possible to provide a ceramic susceptor in which, by applying the structure that allows the height of the bonding agent to be easily adjusted to an appropriate height, such as 20 to 80% of the total height of the support, and to effectively prevent clogging and contamination of the gas holes, the occurrence of arcing can be minimized.

### BRIEF DESCRIPTION OF THE DRAWINGS

The accompanying drawings, which are included as part of a detailed description to aid the understanding of the present disclosure, provide embodiments of the present disclosure, and, together with the detailed description, illustrate the technical idea of the present disclosure, in which:

FIG. 1 is a schematic cross-sectional view of a ceramic susceptor according to an embodiment of the present disclosure;

FIG. 2A is a cross-sectional view of portion AA of FIG. 1 according to a first embodiment;

FIG. 2B is a cross-sectional view of portion AA of FIG. 1 according to a second embodiment;

FIG. 2C is a cross-sectional view of portion AA of FIG. 1 according to a third embodiment;

FIGS. 3A, 3B and 3C are cross-sectional views illustrating a gas hole portion in respective processes of manufacturing a ceramic susceptor according to an embodiment of the present disclosure;

FIGS. 4A, 4B and 4C are cross-sectional views illustrating a gas hole portion in respective processes of manufacturing a ceramic susceptor according to another embodiment of the present disclosure; and

FIG. 5 is a view illustrating the gas hole structure of the conventional ceramic susceptor.

### DETAILED DESCRIPTION OF THE EXEMPLARY EMBODIMENTS

Hereinafter, the present disclosure will be described in detail with reference to the accompanying drawings. Herein, like components in each drawing are denoted by like reference numerals if possible. In addition, detailed descriptions of already known functions and/or configurations will be omitted. In the following description, components necessary for understanding operations according to various embodiments will be mainly described, and descriptions of elements that may obscure the gist of the description will be omitted. In addition, some elements in the drawings may be exaggerated, omitted, or schematically illustrated. The size of each component does not entirely reflect the actual size. Therefore, the descriptions provided herein are not limited by the relative sizes or spacings of the components drawn in each drawing.

In describing the embodiments of the present disclosure, when a detailed description of the known technology related to the present disclosure is determined to unnecessarily obscure the subject matter of the present disclosure, the detailed description will be omitted. In addition, terms to be described later are defined in consideration of functions in the present disclosure, and may vary according to the intention, custom, or the like of a user or operator. Therefore, the definitions of the terms should be made based on the description throughout this specification. Terms used in the detailed description are only for describing the embodiments of the present disclosure, and should not be construed as limiting in any way. Unless expressly used otherwise, singular expressions include the meanings of plural expressions. As used herein, expressions such as “including” or “comprising” are intended to indicate any features, numbers, steps, operations, elements, or some or combinations thereof, and should not be construed to exclude the existence or possibility of one or more other features, numbers, steps, operations, elements, or some or combinations thereof, in addition to those described above.

In addition, terms such as “first” and “second” may be used to describe various components, but the components are not limited by the terms, and these terms are only used for the purpose of distinguishing one component from another.

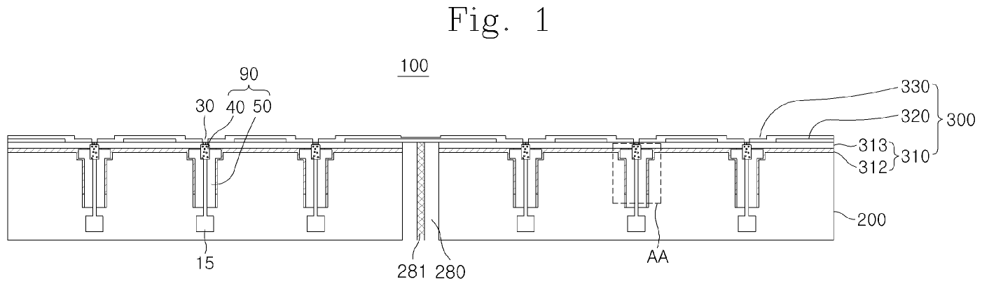

FIG. 1 is a schematic cross-sectional view of a ceramic susceptor 100 according to an embodiment of the present disclosure.

Referring to FIG. 1, the ceramic susceptor 100 according to an embodiment of the present disclosure includes a base substrate 200 and an insulating plate 300. The ceramic susceptor 100 is preferably of a circular type, but in some cases, may be designed in another shape such as oval or square.

The base substrate 200 may be configured as a multi-layer structure including a plurality of metal layers. These metal layers may be bonded through a brazing process, a welding process, a bonding process, or the like. The insulating plate 300 may be fixed on the base substrate 200 using specific certain fixing means or adhesive/bonding means. The base substrate 200 and the insulating plate 300 may be manufactured separately and then bonded to each other. In some cases, the structure of the insulating plate 300 may be formed directly on the top surface of the base substrate 200 using a ceramic sheet or the like.

As illustrated in FIG. 1, the insulating plate 300 may include an insulating layer 310, an electrode layer 320 on the insulating layer 310, and a dielectric layer 330 on the electrode layer 320.

The insulating layer 310 may be made of a ceramic material. In an embodiment, the insulating layer 310 may be made of a material selected from among materials, such as aluminum oxide (Al₂O₃), aluminum nitride (AlN), silicon carbide (SiC), silicon nitride (Si₃N₄), silicon oxide (SiO₂), barium oxide (BaO), zinc oxide (ZnO), cobalt oxide (CoO), tin oxide (SnO₂), zirconium oxide (ZrO₂), Y₂O₃, YAG, YAM, and YAP. The insulating layer 310 may be formed on the top surface of the base substrate 200 using the above-mentioned ceramic materials by performing a thermal spray coating process, a ceramic sheet bonding process, or the like. The insulating layer 310 formed in this way functions to insulate the base substrate 200 from the electrode layer 320.

The electrode layer 320 may be made of a conductive metal material. As an example, the electrode layer 320 may be made of at least one of silver (Ag), gold (Au), nickel (Ni), tungsten (W), molybdenum (Mo), and titanium (Ti). More preferably, the electrode layer 320 may be made of tungsten (W). The electrode layer 320 may be provided through a thermal spray coating process or a screen printing process. The electrode layer 320 has a thickness of about 1.0 μm to 100 μm. For example, preferably, when providing the electrode layer 320 through a screen printing process, a thickness of 1.0 to 30 μm may be applied, and when providing the electrode layer 320 through the thermal spray coating process, a thickness of 30 to 100 μm may be applied. However, forming an excessively thin electrode layer 320 (e.g., less than 1.0 μm) is difficult and therefore undesirable. In addition, such a thin electrode layer is undesirable because the resistance value increases due to porosity and other defects in the electrode layer, which may lead to a decrease in the electrostatic attractive force as the resistance value increases. In addition, if the electrode layer 320 is excessively thick (e.g., exceeding 100 μm), arcing may occur, which is undesirable. Therefore, it is desirable to ensure that the electrode layer 320 has an appropriate thickness in the range of about 1.0 μm to 100 μm. The electrode layer 320 formed in this way can receive a bias to generate an electrostatic force when loading a substrate (not illustrated) placed on the dielectric layer 330, thereby chucking the substrate. When unloading the substrate (not illustrated), dechucking is performed by applying an opposite bias to the electrode layer 320 to cause discharge.

The electrode layer 320 includes electrode patterns for chucking and dechucking, but is not limited thereto. In some cases, the electrode layer may further include electrode patterns for heaters or RF electrode patterns for plasma generation. That is, the ceramic susceptor 100 of the present disclosure is a semiconductor device for processing substrates to be processed for various purposes, such as semiconductor wafers, glass substrates, and flexible substrates. The ceramic susceptor may include an electrostatic chuck electrode on the electrode layer 320 to be used as an electrostatic chuck to support a substrate to be processed, or may include a heating wire (or heating element) to heat the substrate to be processed to a predetermined temperature. Alternatively, the ceramic susceptor may include an RF electrode additionally or instead of the heating wire for processing such as plasma enhanced chemical vapor deposition on a substrate to be processed.

The dielectric layer 330 may be made of a ceramic material. In an embodiment, the dielectric layer 330 may be made of a material selected from among materials, such as aluminum oxide (Al₂O₃), aluminum nitride (AlN), silicon carbide (SiC), silicon nitride (Si₃N₄), silicon oxide (SiO₂), barium oxide (BaO), zinc oxide (ZnO), cobalt oxide (CoO), tin oxide (SnO₂), zirconium oxide (ZrO₂), Y₂O₃, YAG, YAM, and YAP, which are the same material as the insulating layer 310 described above.

The dielectric layer 330 may be formed on the top surfaces of the insulating layer 310 and the electrode layer 320 using the above-mentioned ceramic materials by performing a thermal spray coating process, a ceramic sheet attachment process, or the like. The dielectric layer 330 formed in this way may serve as a dielectric body to allow the formation of electrostatic force is formed by the electrode layer 320, and also serve as a protective film against the external environment.

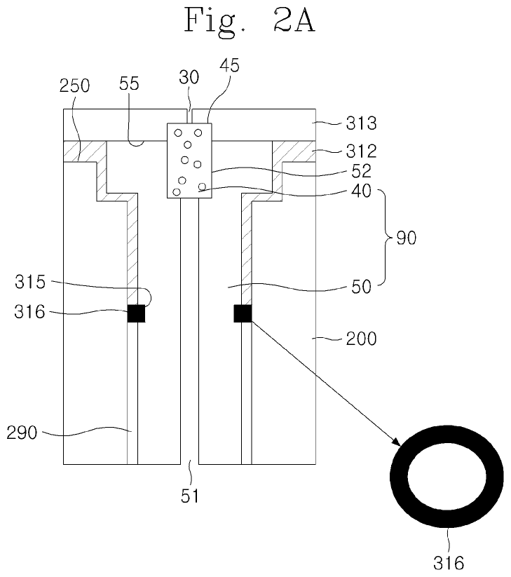

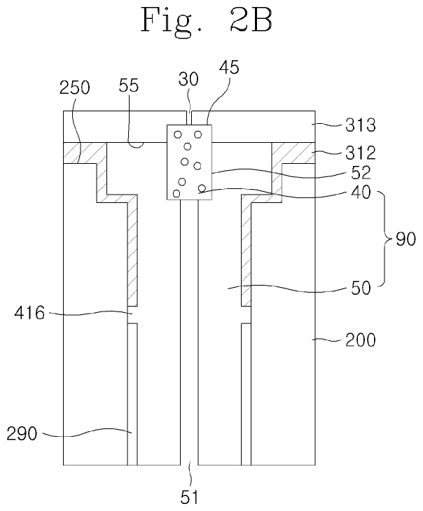

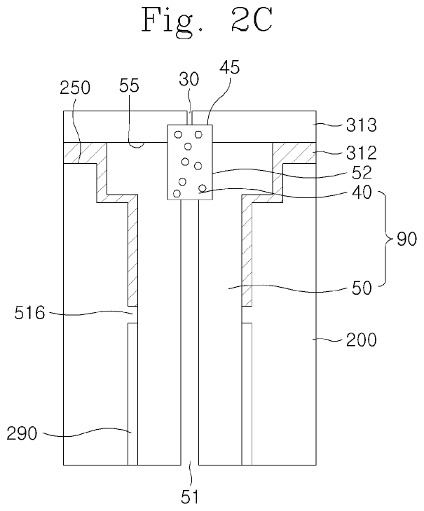

When the ceramic susceptor 100 is mounted inside a chamber for a semiconductor process, the base substrate 200 and the insulating plate 300 may include a predetermined cooling structure, as illustrated in FIGS. 2A to 2C, to uniformly cool the substrate (e.g., a glass substrate, a flexible substrate, or a semiconductor wafer substrate) on the insulating plate 300 using an external cooling gas.

FIG. 2A is a cross-sectional view of portion AA of FIG. 1 according to a first embodiment.

FIG. 2B is a cross-sectional view of portion AA of FIG. 1 according to a second embodiment.

FIG. 2C is a cross-sectional view of portion AA of FIG. 1 according to a third embodiment.

Referring to FIGS. 2A, 2B, and 2C, for example, the base substrate 200 has a cooling gas flow path 15 in an appropriate pattern inside, as illustrated in FIG. 1, for supplying cooling gas. The cooling gas flow path 15 is in fluid communication with the cooling gas holes 30 of the insulating plate 300 through communication holes 51 and porous filters 40 of porous structures 90 of the present disclosure, thereby allowing the cooling gas to be emitted from the cooling gas holes 30 to uniformly cool the substrate on the insulating plate 300. In this case, helium gas (He) may be mainly, but not necessarily, used as the cooling gas. The insulating plate 300 may be provided with an appropriate number of cooling gas holes 30 depending on the design.

In FIG. 1, by applying a bias to the electrode layer 320 from a predetermined electrode rod 281 provided through a hole 280 at the bottom of the ceramic susceptor 100, for example, chucking and dechucking may be performed. The cooling gas holes 30 may be provided in an appropriate number between predetermined electrode patterns forming the electrode layer 320 depending on the design, and may be formed to allow fluid communication through the communication holes 51 and porous filters 40 of the porous structures 90 from the cooling gas flow paths 15 to the top surface of the insulating plate 300.

The ceramic susceptor 100 having the cooling gas holes 30 according to an embodiment of the present disclosure includes the porous structures 90, each of which is mounted between the base substrate 200 and the insulating layer 310 of the insulating plate 300 to allow a gas flow path 15 and a gas hole 30 to communicate with each other.

The pore structures 90 each include a support 50, a porous filter 40, and a fluid stopper (316 in FIG. 2A, 416 in FIG. 2B, and 516 in FIG. 2C), which are fixed to a groove 290 in the base substrate 200. The support 50 has a communication hole 51 that communicates with a gas flow path 15 in the base substrate 200. The support 50 has, on the upper side, a seating groove 52 that communicates with the communication hole 51 and has a larger diameter than the communication hole 51. The porous filter 40 may have an appropriate shape, such as a cylindrical shape, and is provided on the support 50, that is, in the seating groove 52 in the support 50, so as to be embedded between the communication hole 51 in the porous structure 90 and the gas hole 30 in the insulating plate 300. In this case, the porous filter 40 is manufactured/formed to extend beyond the end of the seating groove 52 in the support 50, that is, the top surface 55 of the support 50, so that the porous filter protrudes toward the insulating plate 300. In some cases, the porous filter 40 may be manufactured/formed at a height lower than or equal to the end of the seating groove 52 in the support 50.

It is preferable that the overall appearance of the support 50 has a larger diameter in the portion corresponding to the seating groove 52 than in the portion corresponding to the communication hole 51 to ensure that the shortest distance from the porous filter 40 to the outside of the support 50 does not become smaller, and that the support 50 maintains a predetermined thickness or more without any portion becoming thinner, thereby creating a structure that is resistant to arcing.

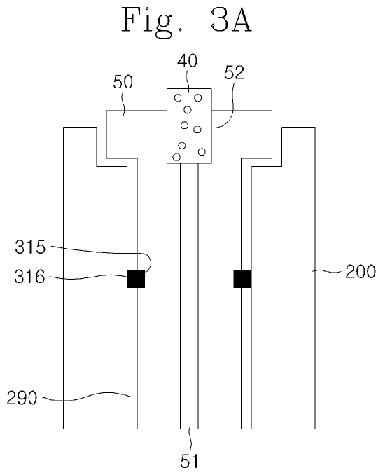

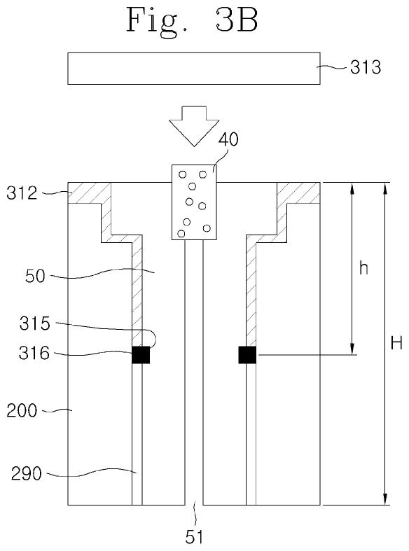

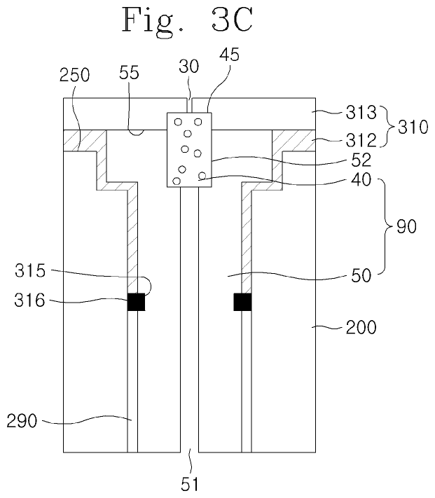

In addition, the support 50 may include a fluid stopper 316, 416, or 516 disposed on the outer side surface thereof. The fluid stopper 316, 416, or 516 ensures that the bonding agent 312, which bonds the base substrate 200 and the insulating plate 300, does not extend beyond the space between the base substrate 200 and the support 50 and is confined to that space. By the fluid stopper 316, 416, or 516, the height h of the space between the base substrate 200 and the support 50 filled with the bonding agent 312 may be 20 to 80%, preferably 50 to 80%, of the total height H of the support 50 from the top surface 55 of the support 50 (see FIG. 3B).

For example, as illustrated in FIG. 2A, the fluid stopper 316 may include a ring-shaped sealing member 316 that is partially accommodated in a groove 315 formed along the perimeter (e.g., a circular outer peripheral surface or a polygonal outer surface) of the support 50 and is disposed in a space between the groove 315 and the base substrate 200, to confine the bonding agent 312. The horizontal and vertical lengths of the cross section of the groove 315 are preferably smaller than the width of the space between the groove 315 and the base substrate 200, and the radial thickness of the ring-shaped sealing member 316 is preferably larger than the width of the space between groove 315 and the base substrate 200. The cross-sectional shape of the ring-shaped sealing member 316 is exemplified as a square in FIG. 2A, but is not limited thereto, and the cross-sectional shape of the ring-shaped sealing member 316 may have various shapes such as a circle, an oval, or a trapezoid.

For example, as illustrated in FIG. 2B, the fluid stopper 416 may be a protrusion 416 formed along the perimeter (e.g., a circular outer peripheral surface or polygonal outer surface) of the support 50, and the protrusion 416 may be located in the space between the base substrate 200 and the support 50 to confine the bonding agent 312. The horizontal length of the cross-section of the protrusion 416 may be 0.5 to 2 times the width of the space between the base substrate 200 and the support 50, and the vertical length of the cross-section of the protrusion 416 is preferably 1 to 5 times the width of the space between the base substrate 200 and the support 50.

In addition, for example, as illustrated in FIG. 2C, the fluid stopper 516 may be a protrusion 516 formed on the base substrate 200 to be in contact with the perimeter (e.g., a circular outer peripheral surface or a polygonal outer surface, etc.) of the support 50. Even in this case, similar to FIG. 2B, the protrusion 516 may be located in the space between the base substrate 200 and the support 50 to confine the bonding agent 312. The horizontal length of the cross-section of the protrusion 516 may be 0.5 to 2 times the width of the space between the base substrate 200 and the support 50, and the vertical length of the cross-section of the protrusion 516 is preferably 1 to 5 times the width of the space between the base substrate 200 and the support 50.

The support 50 and the porous filter 40 may be made of a ceramic material, and the porous filter 40 has porous gaps that allow gas to pass therethrough but block contaminants such as particles. Such a ceramic material may be made of a composition obtained by combining, for example one or more of aluminum oxide (Al₂O₃), aluminum nitride (AlN), silicon carbide (SiC), silicon nitride (Si₃N₄), silicon oxide (SiO₂), barium oxide (BaO), zinc oxide (ZnO), cobalt oxide (CoO), tin oxide (SnO₂), and zirconium oxide (ZrO₂).

The ring-shaped sealing member 316 may be made of various materials, but is preferably made of silicone. Accordingly, by being cured together with the bonding agent 312 during the curing process, the ring-shaped sealing member 316 remains as a cured silicone body.

The base substrate 200 has a cooling gas flow path 15 in an appropriate pattern inside for supplying cooling gas, and the cooling gas flow path 15 is in fluid communication with the cooling gas holes 30 in the insulating plate 300 through the porous structures 90 of the present invention, so that the cooling gas can be ejected from the cooling gas holes 30 to uniformly cool the substrate on the insulating plate 300.

A ceramic sheet 313 is formed on the top surface 250 of the base substrate 200 as an insulating layer 310 via the bonding agent 312. In addition, if necessary, the bonding agent 312 may also be formed on the top surface 55 of the support 50. An electrode layer 320 and a dielectric layer 330 are sequentially formed on the insulating layer 310 of the insulating plate 300.

In addition, a coating layer (not illustrated) made of a ceramic material may be added on the top surface 250 of the base substrate 200. In addition, if necessary, a coating layer (not illustrated) may be added on the top surface 55 of the support 50. Before forming the bonding agent 312, the coating layer (not illustrated) may be formed up to a height of the top surface 45 of the porous filter 40 or the top surface 55 of the support 50 or smaller.

In this way, the base substrate 200 and the insulating plate 300 are fixed by the bonding agent 312 therebetween, and in particular, the bonding agent 312 is filled in some of the spaces between the base substrate 200 and the pore structures 90 within the grooves 290 in the base substrate 200. Preferably, the bonding agent 312 is made of a material with a dielectric strength of 20 kV/mm or more and a volume resistance of 10¹² Ωcm or more to be advantageous in preventing arcing. The bonding agent 312 may be in the form of a silicone paste and may firmly bond the base substrate 200 and the insulating plate 300 by pressing and solidifying the base substrate 200 and the insulating plate 300.

Preferably, the gaps between the base substrate 200 and the pore structures 90 within the grooves 290 in the base substrate 200 are 0.1 to 0.8 mm. The height h filled with the bonding agent 312 in the spaces formed by the gaps between the base substrate 200 and the porous structures 90 within the grooves 290 in the base substrate 200 may be 20 to 80%, preferably 50 to 80% (from the top to bottom in the drawing), of the total height H of the supports 50.

The ceramic susceptor 100 according to an embodiment of the present disclosure is proposed to minimize arcing in a high-power ceramic susceptor for a high aspect ratio contact (HARC) by applying porous structures 90 without using ring-shaped sealing members, thereby maintaining a uniform wall thickness without thinning.

In addition, the ceramic susceptor 100 according to an embodiment of the present disclosure allows easy adjustment of the height of the bonding agent to 20 to 80% of the total height of the support 50. Accordingly, the thickness of the bonding agent, such as silicone, for bonding the base substrate 200 and the insulating plate 300 can be increased to 0.2 to 0.4 mm or more. This enables the application of the bonding agent over a wider vertical range compared to conventional structures. In this case, by applying a structure that can effectively prevents clogging and contamination of the gas holes, the occurrence of arcing is minimized.

FIGS. 3A to 3C are cross-sectional views illustrating a gas hole portion in respective processes of manufacturing a ceramic susceptor 100 according to an embodiment of the present disclosure. Here, the manufacturing processes are described based on the structure of the ceramic susceptor 100 according to a first embodiment (FIG. 2A), but may also be similarly applied to a second embodiment (FIG. 2B) and a third embodiment (FIG. 2C).

Referring to FIG. 3A, in an embodiment of the present disclosure, in order to manufacture a ceramic susceptor 100 having a cooling gas hole 30, first, a base substrate 200 having one or more grooves 290 formed in advance to communicate with a gas flow path 15 for supplying a cooling gas is prepared. Within the grooves 290 of the base substrate 200, a support 50 having a communication hole 51 communicating with the gas flow path 15 of the base substrate 200 and provided with a fluid stopper 316, 416, or 516 is placed/inserted. The communication hole 51 of the support 50 extends from one end at the lower side to the upper side, and the upper side of the support 50 has a seating groove 52 that communicates with the communication hole 51 and has a diameter larger than that of the communication hole 51. A porous filter 40 is placed on the support 50 or inserted into the seating groove 52 of the support 50.

In this case, the porous filter 40 is manufactured/formed to extend beyond the end of the seating groove 52 of the support 50, that is, to protrude toward the insulating plate 300. However, the present disclosure is not limited to this, and in some cases, when the porous filter 40 is inserted into the seating groove 52, the porous filter 40 may be manufactured/formed to have a height equal to or lower than the end of the seating groove 52 of the support 50.

The support 50 and the porous filter 40 may be made of a ceramic material, and the porous filter 40 has porous gaps that allow gas to pass therethrough but block contaminants such as particles. Such a ceramic material may be made of a composition obtained by combining, for example, one or more of aluminum oxide (Al₂O₃), aluminum nitride (AlN), silicon carbide (SiC), silicon nitride (Si₃N₄), silicon oxide (SiO₂), barium oxide (BaO), zinc oxide (ZnO), cobalt oxide (CoO), tin oxide (SnO₂), and zirconium oxide (ZrO₂).

Referring to FIG. 3B, after the porous structure 90 including the support 50 and the porous filter 40 is placed in the base substrate 200, a bonding layer is formed using the bonding agent 312 such as silicone paste, and a ceramic sheet 313 to be laminated on the bonding agent 312 is prepared. The bonding agent 312 may be in the form of a silicone paste and may firmly bond the base substrate 200 and the insulating plate 300 by pressing and solidifying the base substrate 200 and the insulating plate 300 including the ceramic sheet 313.

Referring to FIG. 3C, a ceramic sheet 313 is laminated and attached on the bonding agent 312 to form an insulating layer 310. The ceramic sheet 313 described above may be made of a ceramic material, and may be made of a composition obtained by combining, for example, one or more of aluminum oxide (Al₂O₃), aluminum nitride (AlN), silicon carbide (SiC), silicon nitride (Si₃N₄), silicon oxide (SiO₂), barium oxide (BaO), zinc oxide (ZnO), cobalt oxide (CoO), tin oxide (SnO₂), and zirconium oxide (ZrO₂).

Although not illustrated in the drawing, an electrode layer 320 may be formed at an appropriate location on the insulating layer 310 of the insulating plate 300, as illustrated in FIG. 1, and a dielectric layer 330 may be formed thereon. The electrode layer 320 includes electrode patterns for chucking and dechucking, as described above, but is not limited thereto. In some cases, the electrode layer may further include electrode patterns for heaters or RF electrode patterns for plasma generation. The dielectric layer 330 may also be made of the same ceramic material as the ceramic sheet 313.

Thereafter, the upper structure including the ceramic sheet 313, i.e., the insulating plate 300 including the insulating layer 310, the electrode layer 320, and the dielectric layer 330 can be firmly bonded to the base substrate 200 through the pressing and solidifying of the base substrate 200.

In the processes of forming a bonding layer using the bonding agent 312 and attaching the ceramic sheet 313, the bonding agent 312 is applied/formed on the top surface 250 of the base substrate 200 (if necessary, the bonding agent 312 is also formed on the top surface 55 of the support 50). Through the pressing as described above, the base substrate 200 and the insulating plate 300 are fixed by the bonding agent 312. In particular, the bonding agent 312 is filled in some spaces between the base substrate 200 and the porous structure 90 within the grooves 290 of the base substrate 200. Preferably, the bonding agent 312 is made of a material with a dielectric strength of 20 kV/mm or more and a volume resistance of 10¹² Ωcm or more to be advantageous in preventing arcing.

Preferably, the gaps between the base substrate 200 and the pore structures 90 within the grooves 290 in the base substrate 200 are 0.1 to 0.8 mm. The height h filled with the bonding agent 312 in the spaces formed by the gaps between the base substrate 200 and the porous structure 90 within the grooves 290 in the base substrate 200 may be 20 to 80%, preferably 50 to 80% (from the top to bottom in the drawing), of the total height H of the support 50 by being confined by the fluid stopper 316, 416, or 516.

For example, as illustrated in FIG. 2A, when a ring-shaped sealing member 316 is used as the fluid stopper 316 and is disposed in the space between the groove 315 formed along the perimeter (e.g., a circular peripheral outer surface or a polygonal outer surface) of the support 50 and the base substrate 200, the bonding agent 312 may be confined to a position where the ring-shaped sealing member 316 is disposed, i.e., to the height h from the top surface 55 of the support 50. In addition, for example, as in illustrated FIG. 2B, when using a protrusion 416 formed along the perimeter (e.g., a circular outer peripheral surface or a polygonal outer surface) of the support 50 as the fluid stopper 416, the bonding agent 312 may be confined to the position where the protrusion 416 is disposed, that is, to the height h from the top surface 55 of the support 50. In addition, for example, as illustrated in FIG. 2C, when using a protrusion 516 itself formed on the base substrate 200 to be in contact with the perimeter (e.g., a circular outer peripheral surface or a polygonal outer surface, etc.) of the support 50 as the fluid stopper 516, the bonding agent 312 may be confined to the position where the protrusion 516 is disposed, that is, the height h from the top surface 55 of the support 50.

In addition, as illustrated in FIG. 3C, when attaching the ceramic sheet 313 on the bonding agent 312, a gas hole 30 may be processed in advance in the ceramic sheet 313 at a position corresponding to the porous filter 40. However, the present disclosure is not limited thereto, and it is also possible to process a gas hole 30 that penetrates from the outside of the dielectric layer 330 to the porous filter 40 at the position corresponding to the porous filter 40 after the step of forming the electrode layer 320, that is, after forming the dielectric layer 330. At the position corresponding to the porous filter 40, an appropriate number of gas holes 30 may be formed considering the size (e.g., the diameter) of the porous filter 40.

The holes may be processed using laser processing or the like to have a diameter of 0.1 to 1 mm. The electrode layer 320 is not formed vertically below the cooling gas holes 30. In addition, the dielectric layer 330 is formed on the electrode layer 320, but the dielectric layer 330 is not necessarily formed vertically below the cooling gas holes 30 of the insulating plate 300. The dielectric layer 330 may not be formed as needed.

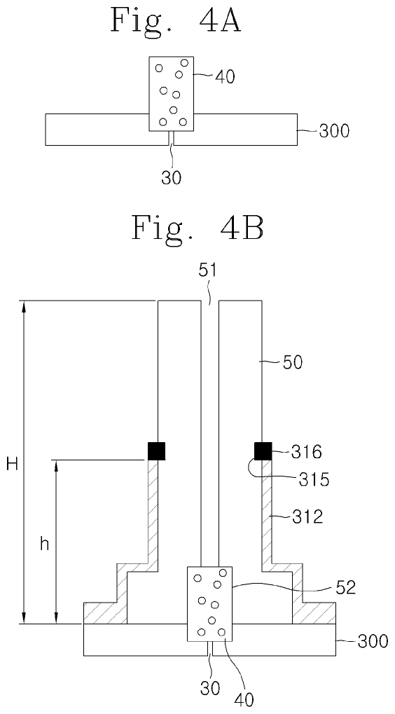

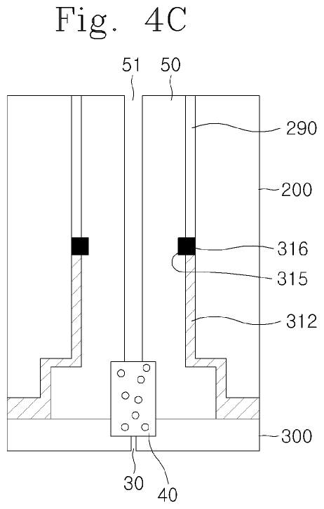

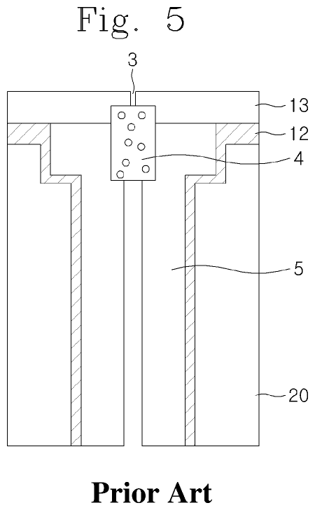

FIGS. 4A to 4C are cross-sectional views illustrating a gas hole portion in respective processes of manufacturing a ceramic susceptor according to another embodiment of the present disclosure. Here, the manufacturing processes are also described based on the structure of the ceramic susceptor 100 according to the first embodiment (FIG. 2A), but may also be similarly applied to the second embodiment (FIG. 2B) and the third embodiment (FIG. 2C).

Referring to FIG. 4A, in another embodiment of the present disclosure, in order to manufacture a ceramic susceptor 100 having a cooling gas hole 30, first, a porous filter 40 may be disposed in a groove 360 of an insulating plate 300 including an electrode layer 320 as described above, so that the porous filter is in contact with the gas hole 30 of the pre-processed insulating plate 300. In this case, the porous filter 40 may be manufactured/formed to extend and protrude beyond the end of the seating groove 360 of the insulating plate 300.

Next, as illustrated in FIG. 4B, a support 50 having a communication hole 51 configured to communicate with the porous filter 40 may be disposed such that the communication hole 51 is aligned with the position of the porous filter 40. At this time, the porous filter 40 may be disposed in the seating groove 52 of the support 50. Subsequently, a bonding layer may be formed on the support 50 using a bonding agent 312.

Next, as illustrated in FIG. 4C, a base substrate 200, which has grooves 290 and a gas flow path 15 for supplying cooling gas, is disposed such that the grooves 290 of the base substrate 200 are seated on the support 50 having the communication hole 51 configured to communicate with the gas flow path 15.

Here, in the processes of forming a bonding layer using a bonding agent 312 and disposing the base substrate 200, the bonding agent 312 is applied/formed under the fluid stopper 316, 416, or 516 of the support 50. Subsequently, through pressing, the base substrate 200 and the insulating plate 300 is fixed by the bonding agent 312. In particular, the bonding agent 312 is filled in some spaces between the base substrate 200 and the porous structure 90 within the grooves 290 of the base substrate 200. Preferably, the bonding agent 312 is made of a material with a dielectric strength of 20 kV/mm or more and a volume resistance of 10¹² Ωcm or more to be advantageous in preventing arcing.

Preferably, the gaps between the base substrate 200 and the pore structures 90 within the grooves 290 in the base substrate 200 are 0.1 to 0.8 mm. The height h filled with the bonding agent 312 in the spaces formed by the gaps between the base substrate 200 and the porous structure 90 within the grooves 290 in the base substrate 200 may be 20 to 80%, preferably 50 to 80% (from the top to bottom in the drawing), of the total height H of the support 50 by being confined by the fluid stopper 316, 416, or 516.

For example, as illustrated in FIG. 2A, when a ring-shaped sealing member 316 is used as the fluid stopper 316 and is disposed in the space between the groove 315 formed along the perimeter (e.g., a circular peripheral outer surface or a polygonal outer surface) of the support 50 and the base substrate 200, the bonding agent 312 may be confined to a position where the ring-shaped sealing member 316 is disposed, i.e., to the height h from the top surface 55 of the support 50. In addition, for example, as in illustrated FIG. 2B, when using a protrusion 416 formed along the perimeter (e.g., a circular outer peripheral surface or a polygonal outer surface) of the support 50 as the fluid stopper 416, the bonding agent 312 may be confined to the position where the protrusion 416 is disposed, that is, to the height h from the top surface 55 of the support 50. In addition, for example, as illustrated in FIG. 2C, when using a protrusion 516 itself formed on the base substrate 200 to be in contact with the perimeter (e.g., a circular outer peripheral surface or a polygonal outer surface, etc.) of the support 50 as the fluid stopper 516, the bonding agent 312 may be confined to the position where the protrusion 516 is disposed, that is, the height h from the top surface 55 of the support 50.

As described above, an embodiment of the present disclosure may provide a ceramic susceptor 100 in which, by applying a fluid stopper structure to the bonding structure of the base substrate 200 and the insulating plate 300, which makes it easy to adjust the volume of the bonding agent during the bonding process, clogging of gas holes can be prevented, and contamination around the gas holes can be reduced in a high-power ceramic susceptor or the like for a high aspect ratio contact (HARC) process, thereby minimizing the occurrence of arcing. In addition, a ceramic susceptor may be provided in which, by applying the structure that allows the height h of the bonding agent to be easily adjusted to an appropriate height, such as 20 to 80% of the total height H of the support, and to effectively prevent clogging and contamination of the gas holes, the occurrence of arcing can be minimized.

In the foregoing, the present disclosure has been described based on specific details, such as specific components, limited embodiments, and drawings, but these are only provided to help a more general understanding of the present disclosure, and the present disclosure is not limited to the above-described embodiments. A person ordinarily skilled in the art to which the present disclosure pertains may make various modifications and changes without departing from the essential characteristics of the present disclosure. Therefore, the spirit of the present disclosure should not be limited to the described embodiments, and not only the appended claims, but also all technical ideas that are equivalent to or equivalently modified to the claims should be interpreted as being included in the scope of the present disclosure.

1. A ceramic susceptor comprising:
a base substrate having a gas flow path configured to supply cooling gas;
an insulating plate fixed on the base substrate and having a gas hole; and
a pore structure configured to allow the gas flow path and the gas hole to communicate with each other between the base substrate and the insulating plate, the pore structure including a support fixed to a groove of the base substrate and having a communication hole configured to communicate with the gas flow path, a porous filter embedded between the communication hole and the gas hole on the support, and a fluid stopper disposed on an outer side surface of the support,
wherein a bonding agent bonding the base substrate and the insulating plate is confined in a space between the base substrate and the support by the fluid stopper, and
wherein the fluid stopper is made of silicone, and the porous filter extends beyond a top surface of the support and protrudes toward the insulating plate.

2. The ceramic susceptor of claim 1, wherein the fluid stopper includes a ring-shaped sealing member disposed in a groove formed along the perimeter of the support.

3. The ceramic susceptor of claim 2, wherein the ring-shaped sealing member includes a rectangular, circular, oval, or trapezoidal cross-sectional shape.

4-5. (canceled)

6. The ceramic susceptor of claim 1, wherein a gap between the base substrate and the support within the groove of the base substrate is 0.1 to 0.8 mm.

7. The ceramic susceptor of claim 1, wherein the fluid stopper is disposed at a position of 50 to 80% of a total height of the support.

8. The ceramic susceptor of claim 1, wherein the bonding agent has a dielectric strength of 20 kV/mm or more and a volume resistance of 10¹² Ωcm or more.

9-14. (canceled)
